(19) United States
(12) Patent Application Publication
(10) Pub. No.: US 2014/0217593 A1
(43) Pub. Date: Aug. 7, 2014

(54) Electrical Connecting Element and Method for Manufacturing the Same

(71) Applicant: National Chiao Tung University, Hsinchu (TW)

(72) Inventors: Chih CHEN, Hsinchu (TW); Taochi LIU, Hsinchu County (TW); Yi-Sa HUANG, Hsinchu (TW); Chien-Min LIU, Taichung (TW)

(73) Assignee: National Chiao Tung University, Hsinchu (TW)

(21) Appl. No.: 14/174,178

(22) Filed: Feb. 6, 2014

(30) Foreign Application Priority Data
Feb. 7, 2013 (TW) 102104935
Sep. 26, 2013 (TW) 102134714

(51) Int. Cl. H01L 23/00

(52) U.S. Cl. CPC H01L 24/05; H01L 24/03
USPC 257/762; 438/612

(57) ABSTRACT

An electrical connecting element for connecting a first substrate and a second substrate and a method for manufacturing the same are disclosed. The method of the present invention comprises: (A) providing a first substrate and a second substrate, wherein a first copper film is formed on the first substrate, a first metal film is formed on the second substrate, a first connecting surface of the first copper film has a (111)-containing surface, and the first metal film has a second connecting surface; and (B) connecting the first copper film and the first metal film to form an interconnect, wherein the first connecting surface of the first copper film is faced to the second connecting surface of the first metal film.

### CROSS REFERENCE TO RELATED APPLICATION

This application claims the benefits of the Taiwan Patent Application Serial Number 102104935 and 102134714, respectively filed on Feb. 7 and Sep. 26, 2013, the subject matter of which is incorporated herein by reference.

### BACKGROUND OF THE INVENTION

1. Field of the Invention

The present invention relates to an electrical connecting element and a method for manufacturing the same, especially relates to an electrical connecting element and a method for manufacturing the same for a three dimensional integrated electrical circuit.

2. Description of Related Art

With a rapid development of the electronics industry, requirements for electronic products with small sizes, light weights, multifunction and high performances. In the current development of an integrated circuit, in order to dispose active components and passive components on the same device, semiconductor packaging technology is used to achieve the purpose of accommodating more circuits and electronic components in a limited unit area.

In the semiconductor packaging technology, a solder or a copper film is used to laminate package substrates or circuit boards through compression. In the case that the compression is formed by using an ordinary copper film, small grains without uniform stacking directions are formed due to the lattice of the ordinary copper film lacking unity. Hence, it is necessary to undergo a variety of pretreatment such as fine surface polishing and etching before connecting the substrates, and then thermo-compressing the substrates under a severe environments (such as the environment with nitrogen and acid gas introduced therein). Besides, the temperature of the thermo-compression has to be proceeded at a temperature of 300° C. or more, but this high temperature may cause the components in the circuit boards damaged. Further, although there have been reported that copper films can be connected at room temperature, the surfaces thereof have to be atomically flat, and the environment for the connecting the same has to be an ultrahigh vacuum environment of 10⁻⁸ torr. Therefore, the aforementioned thermo-compression process is not suitable for industrial manufacture.

As shown in FIG. 1A, when two substrates 11, 13 are connecting by copper films 12, 14 without enough flatness, gaps or voids may be easily generated after the compression (as shown in FIG. 1B), resulting in the product reliability decreased.

Due to fine electronic devices are required, the fine interconnects of the products cause the areas of the connecting surfaces reduced. Meanwhile, in order to improve product reliability, the connecting process is relatively more complicated. Therefore, it is desirable to provide a connecting structure and a method for manufacturing the same with the advantages of simple manufacturing process, less voids formed therein, and no solders used, which can be applied to various semiconductor manufacturing processes, and particularly to those for three dimensional integrated circuits to improve the reliability thereof and reduce product cost for manufacturing the same.

### SUMMARY OF THE INVENTION

The main purpose of the present invention is to provide an electrical connection element, wherein a good adhesion is obtained in an interconnect between two substrates (particularly, connecting surfaces), and only few, or even no gaps and voids are formed therein to prevent the interconnect from being broken.

Another object to the present invention is to provide a method for manufacturing an electrical connecting element, in order to manufacture an electrical connection element having high product reliability.

In order to achieve the above mentioned objects, a method for manufacturing an electrical connecting element for electrical connecting a first substrate and a second substrate comprises the following steps: (A) providing a first substrate and a second substrate, wherein a first copper film is formed on the first substrate, a first metal film is formed on the second substrate, a first connecting surface of the first copper film is a (111)-containing surface, and the first metal film has a second connecting surface; and (B) connecting the first copper film and the first metal film to form an interconnect, wherein the first connecting surface of the first copper film is faced to the second connecting surface of the first metal film.

Through the above mentioned method of the present invention, an electrical connection element for electrical connecting a first substrate and a second substrate can be obtained, which comprises: a first substrate; a second substrate; and an interconnect disposed between the first substrate and the second substrate, wherein the interconnect is formed by connecting a first copper film and a first metal film with each other, and a junction between the first copper film and the first metal film comprises a plurality of grains, which stacks along a stacking direction of [111] crystal axis.

In the present invention, the used first copper film has a high preferred [111] direction, in which the highest self-diffusion rate is found, and the (111)-containing surface has the highest stacking density. In the method of the present invention, it should be noted that only the first copper film having a connecting surface with a preferred [111] direction is required to achieve the purpose of forming interconnect with only few, or even without gaps or voids formed therein, and the other can be any copper film or any other heterogeneous metal film having a connecting surface without preferred direction. Even though the first copper film is a polycrystalline copper film and the first metal film is a polycrystalline copper or other heterogeneous metal film, the aforementioned purpose can also be achieved. The reason is that, when at least one copper film with (111)-connecting surface is formed on the substrate (such as a semiconductor wafer or a circuit board, etc.) as an electrical connection medium, the copper lattice at the (111)-connecting surface has a regular direction arrangement, so that gaps or voids are not easily generated in the interconnect even though the thermo-compression of the first copper film and the first metal film is held at low temperature.

Furthermore, in the electrical connection element prepared by the method of the present invention, grains having preferred (111) directions can be formed in the connecting portion (i.e. the junction), and no gaps are formed therein. Since there is no gap formed in the interconnect between the first substrate and the second substrate, the risk of the interconnect broken can be reduced, the reliability and the usage lifetime of the components can be improved, and the high conductivity and high heat dispersion of copper can be maintained. In particular, in the electrical connecting element prepared by the method of the present invention, the interconnect without gaps formed therein, which is obtained by connecting copper and a heterogeneous metal material, can still be achieved.

In the present invention, the material of the first metal film and the first copper film may be the same or different. Preferably, the material of the first metal film is selected from a group consisting of gold, silver, platinum, nickel, copper, titanium, aluminum, and palladium.

In one aspect of the present invention, the first metal film is a second copper film. Herein, the material of the first copper film and the second copper film are not particularly limited, as long as one of the connecting surfaces thereof is a (111)-containing surface. For example, the first copper film of the present invention can be a copper layer having a connecting surface of a (111)-containing surface, and the second copper film is a polycrystalline copper layer without preferred direction; or the first copper film and the second copper film of the present invention can respectively be a copper layer or a nanotwinned copper layer having a connection surface of a (111)-connecting surface. After the thermo-compression process, both of the copper layer (which includes a polycrystalline copper layer) or a nanotwinned copper layer can form an interconnect, in which the joint is formed by a plurality of grains stacking along a stacking direction of [111] crystal axis. Preferably, these grains are columnar grains. The term “(111) surface” in the present invention means: an angle of 15° included between a normal vector of the (111) surface of a plurality of copper grains of the copper film and a normal vector of the connecting surface. Based on the aforementioned definition, “the (111)-containing surface” means 40-100% of a total area of the connecting surface is a (111) surface; preferably, 50-100% of a total area thereof is a (111) surface; and more preferably, 60-100% of a total area thereof is a (111) surface. If both the first copper film and the second copper film are nanotwinned copper layers, 50% or more volume of the nanotwinned copper layer preferably comprises a plurality of grains. Since the twinned crystal arrangement of the nanotwinned copper can improve the electron migration resistance of a copper film, thus the reliability of the product can be increased and particularly suitable for the production of an integrated circuit.

In one aspect of the present invention, the material of the first metal film may be gold, silver, platinum, nickel, titanium, aluminum, palladium, or alloys thereof. Herein, the materials of the first copper film and the connecting surface thereof are the same as previously mentioned, thus they are not further described.

The method for manufacturing the electrical connecting element of the present invention, further comprises a step (A′) prior to the step (A): cleaning the first connecting surface of the first copper film and the second connecting film of the first metal film with an acid to remove the oxidant or other impurities thereon. In particular, an acid solution (such as a hydrochloric acid) is used to clean the first connecting surface of the first copper film and the second connecting surface of the first metal film. Furthermore, in the method for manufacturing the electrical connecting element of the present invention, in the step (B), the means for connecting is not particularly limited, and the technique commonly used in the art, such as connecting by the clamps can be used. Further, the first copper film and the first metal film may also be connected with each other with a pressure. However, the pressure applied thereto is not particularly limited. Preferably, the thermo-compression process is performed at low pressure, such as 1.5-5 kg/cm².

Furthermore, in the method for manufacturing the electrical connecting element of the present invention, the step (B) may be performed at an elevated temperature, and the connecting temperature is not particularly limited, as long as the thermo-compression is finished without destroying the structures of both the substrates. For example, the thermo-compression can be performed at the low temperature of 100-400° C. Preferably, the first copper film and the first metal film are connected with each other with a pressure at 150-300° C. In this case, the connecting temperature in the step (B) is preferably 150-400° C. and more preferably 150-250° C. Besides, the connecting time is not particularly limited, as long as both the substrates can be connected well. For example, the connection time can be about 0.1 to 5 hours, and preferably is about 0.1 to 1.5 hours.

In the method for manufacturing the electrical connecting element of the present invention, in the step (B), the first copper film and the first metal film can be connected with each other under low vacuum, and preferably under 1-10⁻³ torr.

The connecting surface of the first copper film is a (111) surface while the connecting is proceeded for manufacturing the electrical connection element of the present invention. The (111) surface has a relative high diffusion rate as well as a relative low surface energy, and a face-centered cubic (FCC) close-packed surfaces, so the interconnect without gaps can be easily achieved. When either the polycrystalline copper or the nanotwinned copper is used as a film material, as long as the first connecting surface containing (111) preferred direction, the interconnect with few voids can be obtained even though the connecting surface thereof is only cleaned with a simple polishing process in advance. The diffusion rate of the copper atoms in the (111) surface is very fast, so excellent connecting effect of the joint can be obtained at 200° C. or less. Hence, the restrictions for the thermo-compression can accordingly be reduced, the expensive equipment is not further required, and thus the production cost thereof can be greatly decreased.

In the electrical connection element and the method of the present invention, the nanotwinned copper grains are columnar twinned grains. Further, a plurality of grains connect to each other, each grain is formed by a plurality of nanotwinned copper stacking along a stacking direction of crystal axis, and an angle included between the stacking directions of adjacent grains is 0-20°.

Furthermore, in the method for manufacturing the electrical connecting element of the present invention, the first copper film and the second copper film having nanotwinned copper or polycrystalline copper containing (111) surface can be formed through DC plating or pulse plating. Preferably, the nanotwinned copper or the polycrystalline copper containing the (111) surface is prepared by the following steps: providing a plating apparatus, comprising an anode, a cathode, a plating solution, and a power supply, wherein the power supply connects to the anode and the cathode, and the anode and cathode lines are immersed in a plating solution; and growing a nanotwinned copper film from the surface of the cathode through a plating process performed with the power supply. Here, the plating solution to be used can include: a copper salt, an acid, and a chloride ion.

In the plating solution mentioned above, one of the main function of the chloride ion is to fine adjust the grain growth direction to let copper layer (particularly, a twinned copper layer) have a preferred crystal orientation. In addition, the acid may be an organic acid or an inorganic acid to increase the concentration of electrolyte and to improve a plating rate. The examples of the acid may comprise sulfuric acid, methane sulfonic acid, or a mixture thereof. In addition, the concentration of the acid in the plating solution preferably is 80-120 g/L. Furthermore, a plating solution has to contain copper ions which can be obtained from the copper salt, such as copper sulfate or methane copper sulfonate. The preferred composition of the plating solution may further include an additive selected from a group consisting of gelatin, surfactants, lattice modification agent, and a mixture thereof to adjust the grain growth direction to obtain copper layer containing (111) preferred direction.

The power supply used in the plating device is preferably a DC plating supply, a high-speed pulse plating supply or both of them used alternately to enhance the growing rate of the metal layer. When the DC plating supply is used in the step (B), the current density may be preferably 1-12 ASD, and more preferably is 2-10 ASD (such as 8 ASD). When the high-speed pulse plating supply is used in the step (B), the operating condition is preferably: Tₒₙ/T_{off} (sec) being 0.1/2-0.1/0.5 (such as 0.1/2, 0.1/1, or 0.1/0.5), the current density being 1-25 ASD (preferably, 5 ASD). Under the aforementioned conditions, the growth rate of the copper layer is calculated by the actual power on hours, and preferably is 2-2.64 μm/min. For example, when the plating current density is 8 ASD, the growth rate of the metal layer is 1.5-2 μm/min (such as 1.76 μm/min). In addition, the thickness of the copper layer can be adjusted according to the period of the plating time. In the present invention, the thickness thereof is preferably about 0.1-500 μm, more preferably 0.8-200 μm, and most preferably 1-20 μm.

In particular, the twinned crystal copper having a preferred direction manufactured by the conventional technique does not have fill-hole property, and the thickness is only up to about 0.1 μm in the mass production. Hence, it can be used as a seed layer, and cannot be directly applied as wires. However, the thickness of the nanotwinned copper plating layer can be up to 0.1-500 μm manufactured by the aforementioned method of the present invention, and may be formed directly in the opening or the trench of the dielectric layer. Therefore, the nanotwinned copper playing layer of the present invention can be applied to produce the lines of the circuit board.

In addition, the cathode or the plating solution can be held at 50-1500 rpm rotational speed to help the grain growth direction and the speed when performing the plating process. The grain diameter of the nanotwinned copper layer of the present invention preferably is 0.1-50 μm, and more preferably is 1-10 μm; and the grain thickness thereof preferably is 0.01-500 μm, and more preferably is 0.1-200 μm.

Furthermore, in the electrical connection element and the method of the present invention, each the first substrate and the second substrate may independently be a semiconductor chip, a package substrate, or a circuit board; and preferably is a semiconductor wafer. Hence, the present invention can be applied to a flip chip packaging, a wafer bonding, a wafer level chip scale packaging (WLCSP) and other common used packaging techniques derived from IBM C4, and especially applied to those with high frequency and high power components. In particular, the present invention can be applied to the three dimensional integrated circuit which have to be met with the requirement of high mechanical properties and product reliability. For example, when both the first substrate and the second substrate are semiconductor wafers, the so-called three-dimensional integrated circuit (3D-IC) can be formed after connecting the same. Moreover, in other case, the three dimensional integrated circuit can be used as the first substrate, and the package substrate can be as the second substrate to proceed the connecting process. Here, the aforementioned devices are only the way of example, and not be used to limit the present invention.

### BRIEF DESCRIPTION OF THE DRAWINGS

FIG. 1A is a schematic view of a conventional interconnect element.

FIG. 1B is an enlarged schematic view of a connecting portion of a conventional interconnect element.

FIG. 2A to 2C are cross-sectional views of a process for manufacturing an electrical connecting element having nanotwinned copper layer according to Example 1 of the present invention.

FIG. 3 is a schematic view of a plating apparatus for forming a copper film according to Example 1 of the present invention.

FIG. 4 is a vertical view of an electron backscattered diffraction of a copper layer according to Example 1 of the present invention.

FIGS. 5A and 5B are respectively a focused ion beam cross-sectional view and a schematic view of a nanotwinned copper layer according to Example 1 of the present invention.

FIG. 6 is a focused ion beam cross-sectional view of a connecting portion of an electrical connecting element according to Example 2 of the present invention.

FIGS. 7A-7B are cross-sectional views of a process for manufacturing an electrical connecting element having a nanotwinned copper layer according to Example 2 of the present invention.

FIGS. 8A-8C are cross-sectional views of a process for manufacturing an electrical connecting element formed by a copper layer according to Example 3 of the present invention.

FIG. 9 is a vertical view of an electron backscattered diffraction of a copper layer according to Example 3 of the present invention.

FIG. 10 is a cross-sectional image in a bright field of a copper layer observed by a transmission electron microscope according to Example 3 of the present invention.

FIG. 11 is a high resolution transmission electron microscope image of a connecting portion of an electrical connecting element according to Example 3 of the present invention.

FIG. 12 is a cross-sectional image in a bright field of a connecting portion of an electrical connecting element observed by a transmission electron microscope according to Example 3 of the present invention.

FIG. 13 is a focused ion beam cross-sectional view of a connecting portion of an electrical connecting element according to Example 4 of the present invention.

FIG. 14 is a cross-sectional image in a bright field of a connecting portion of an electrical connecting element observed by a transmission electron microscope according to Example 5 of the present invention.

FIG. 15 is an image in a bright field of a connecting portion of an electrical connecting element observed by a transmission electron microscope according to Example 6 of the present invention.

FIG. 16 is a cross-sectional image in a bright field of a connecting portion of an electrical connecting element observed by a transmission electron microscope according to Example 7 of the present invention.

FIG. 17 is a vertical view of an electron backscattered diffraction of a copper layer containing 64% of a (111) surface according to Example 8 of the present invention.

FIG. 18 is a transmission electron microscope cross-sectional image in a bright field of a connecting portion of an electrical connecting element observed by a transmission electron microscope according to Example 8 of the present invention.

FIG. 19 is a focused ion beam cross-sectional view of a connecting portion of an electrical connecting element according to Example 9 of the present invention.

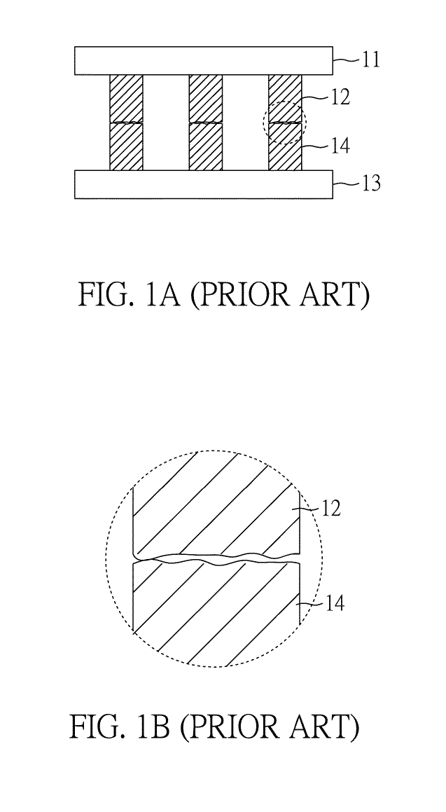

### DETAILED DESCRIPTION OF THE PREFERRED EMBODIMENT

The preset invention is illustrated by the following specific embodiments, and those skilled in the art can readily understand the advantages and efficiency of the present invention according to the content of the present specification. The present invention may also be implemented or applied by various other specific embodiments, the details of the specification can be changed and modified without departing from the spirit of the invention based on different perspectives and applications.

### Example 1

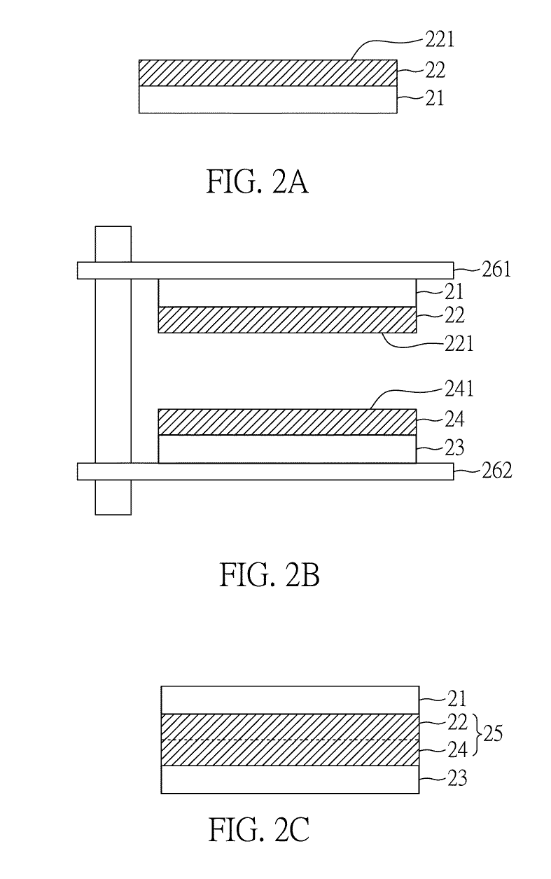

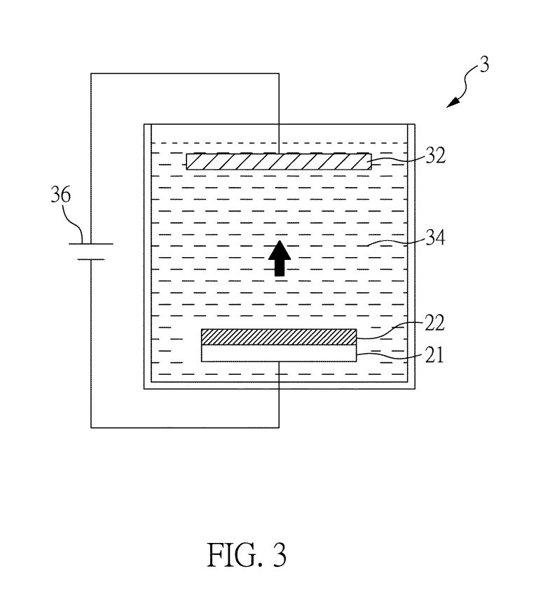

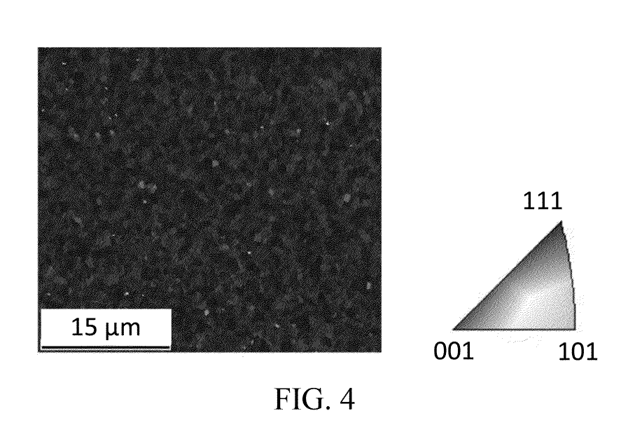

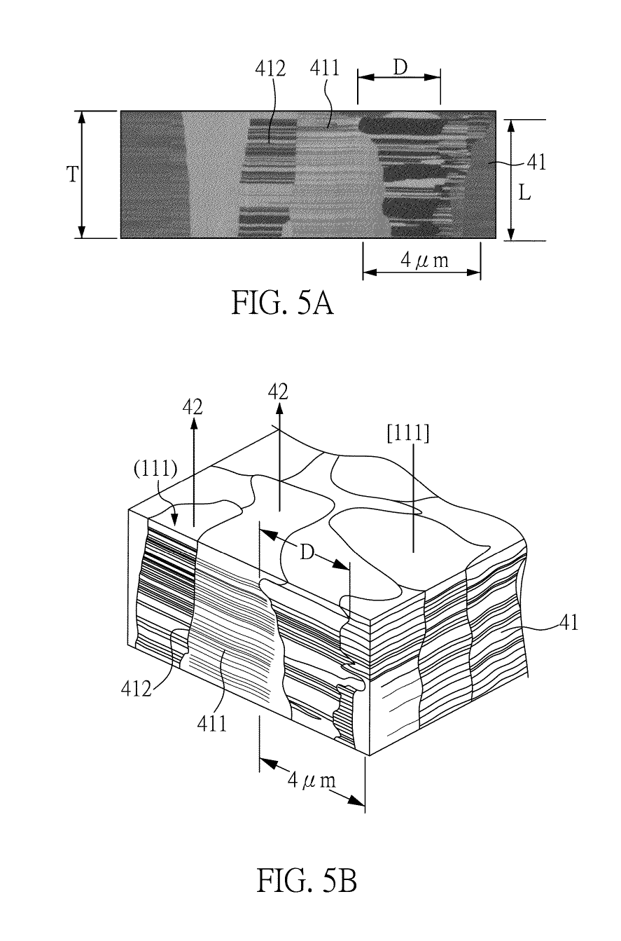

FIGS. 2A to 2C are cross-sectional views showing a process for manufacturing an electrical connection element having a twinned crystal copper layer of the present embodiment. The schematic view of a plating apparatus for forming the copper film in the present embodiment is shown in FIG. 3. A vertical view of an electron backscattered diffraction of the copper layer in the present embodiment is shown in FIG. 4, in which the ratio of the (111) surface is 100%. The focused ion beam cross-sectional view and a schematic view of the nanotwinned copper layer of the present embodiment are respectively shown in FIGS. 5A and 5B.

First, a first substrate 21 is provided, which is a wafer, as describes in FIG. 2A. In order to describe briefly, only the schematic view the first substrate 21 is exemplified, and circuits, active components, passive components or other components are not disclosed in the drawings.

Then, a plating process is performed on the first substrate 21 with the plating apparatus shown in FIG. 3. As shown in FIG. 3, the first substrate 21 is placed in a plating apparatus 3 as the cathode, wherein the plating apparatus 3 comprises an anode 32, which is immersed in the plating solution 34 and connected to a DC power supply source 36 (Keithley 2400 is sued herein). The material of the anode 32 may be copper, a phosphor bronze or an inert anode (such as titanium rhodium); and the material used for the anode 32 is copper in the present embodiment. Further, the plating solution 34 includes copper sulfate (wherein the concentration of copper ions is 20-60 g/L), chloride ions (wherein the concentration thereof is 10-100 ppm), and methacrylic acid (wherein the concentration thereof is 80-120 g/L), and other surfactants or lattice modification agents can be added (such as BASF Lugalvan with a concentration of 1-100 ml/L) therein. The plating solution 34 of the present embodiment may further optionally contain an organic acid (such as methane sulfonic acid), a gelatin, or a mixture thereof to adjust the grain structure and the size.

Next, as shown in FIG. 2A, a plating process is performed with a direct current having a current density of 2-10 ASD to grow the first copper film 22 on the surface of the first substrate 21, and the direction thereof is indicated with the arrow shown in FIG. 3. The (111) surface of the twinned crystal and the surface of the first copper film 22 are approximately perpendicular to the direction of the electric field during the plating process, and the twinned crystal copper is grown at a rate of about 1.76 μm/min. More specifically, the first copper film 22 (i.e. the nanotwinned copper layer) is grown along a direction perpendicular to (111), which means the first copper film 22 is grown in a direction parallel to the direction of the electric field.

The obtained first copper film 22 includes a plurality of twinned crystal copper grains, which are composed from a plurality of twinned copper. The nanotwinned copper grains are extended to the surface, thus the first copper film surface 22 is also a (111) surface. The thickness of the obtained first copper film 22 is around 5˜20 μm, and the [111] crystal axis thereof is vertical to the axis of the (111) surface and the ratio of (111) surface is 100%. Then, the first substrate 21 is removed from the plating apparatus, the first substrate 21 with the first copper film 22 formed thereon can be obtained, the first copper film 22 is a nanotwinned copper layer and the first connecting surface 221 thereof is a (111) surface, wherein the ratio of the (111) surface is 100%. A vertical view of an electron backscattered diffraction (EBSD) thereof is shown in FIG. 4, wherein the area of the blue part is a (111) surface.

Herein, FIGS. 5A and 5B are respectively a focused ion beam (FIB) cross-sectional view and schematic view of the nanotwinned copper layer as the first copper film of the present embodiment. As shown in FIG. 5A, more than 50% of the volume of the nanotwinned copper layer comprises a plurality of columnar grains 41, and each of the grain has a plurality of layered nanotwinned copper (for example, a group of adjacent black and white lines form a twinned crystal copper, which stacks along the stacking direction 42 to constitute the grain 41, as shown in FIG. 5B). In the present invention, the nanotwinned copper layer contains a lot of nanotwinned copper. Herein, the diameter D of these columnar grains 41 are about 0.5 μm to 8 μm, a height L thereof is around 2 μm to 20 μm, and the surface 411 of the nanotwinned grain (horizontal lines) is parallel to the (111) surface. A grain boundary 412 is located between adjacent the twinned crystal grains, the (111) surface of the copper layer is perpendicular to the thickness direction T thereof, and the thickness T thereof is around 20 μm (which can be adjusted in a range from 0.1 μm to 500 μm). An angle included between the stacking directions of adjacent grains are within 0° to 20° (which is almost equivalent to the [111] crystal axis).

Referring to FIG. 2B, a second substrate 23 is provided, which is also a wafer. Similarly, in order to describe briefly, only the schematic view of the second substrate 23 is exemplified, and the circuits, the active components, passive components or other components are not disclosed in the drawings.

Meanwhile, the second copper film 24 is formed on the second substrate 23 through the same plating method for forming the first copper film 22, wherein the obtained second copper film 24 has a thickness about 5˜20 μm, and the [111] crystal axis is vertical to the (111) surface. Accordingly, the second copper film 24 is a nanotwinned copper film, and a second connecting surface 241 is also a (111) surface. The nanotwinned copper films of the second copper film 24 and the first copper film 22 have the same structure and will not be further described herein.

The first connecting surface 221 of the first copper film 22 and the second connecting surface 241 of the second copper film 24 are respectively cleaned by an aqueous solution of hydrochloric acid (the volume ratio between hydrochloric acid and the deionized water is 1:1). The first substrate 21 and the second substrate 23 are respectively placed on the clamps 261, 262, and the first connecting surface 221 is faced to the second connecting surface 241. Then, the first substrate 21 and the second substrate 23 are placed in a vacuum furnace under 10⁻³ torr, the temperature of the vacuum furnace is raised to 200° C. to perform the connecting process and the annealing process for 1 hour. During the connecting process, the pressure therein is appropriately adjusted to maintain the twinned grain structure of the first copper film 22, the second copper film 24 and the junction therebetween.

After the aforementioned process, the electrical connection element having twinned copper of the present embodiment can be obtained, as shown in FIG. 2C, which comprises: a first substrate 21; a second substrate 23; and an interconnect 25 disposed between the first substrate 21 and the second substrate 23, wherein the interconnect 25 is obtained from the first copper film 22 and the second copper film 24 connected to each other, the material of the interconnect 25 is a nanotwinned copper layer, and 50% or more volume of the nanotwinned copper layer comprises a plurality of grains. Herein, the interconnect 25 is formed by the first copper film 22 and the second copper film 24 after a connecting process, and the connecting portion (i.e. junction) therebetween is shown as a dotted line.

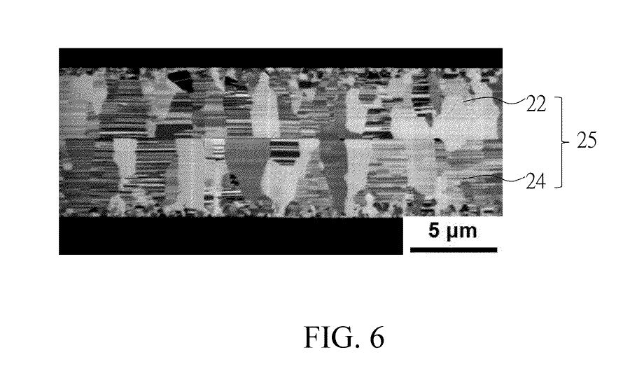

The focused ion beam cross-sectional view of the connecting portion of the electrical connection element having a twinned copper of the present embodiment is shown in FIG. 6. The result shows that, while the (111) surface is served as a connecting surface, there are no voids or gaps observed in the connecting portion of the interconnect 25 formed by the first copper film 22 and the second copper film 24.

### Example 2

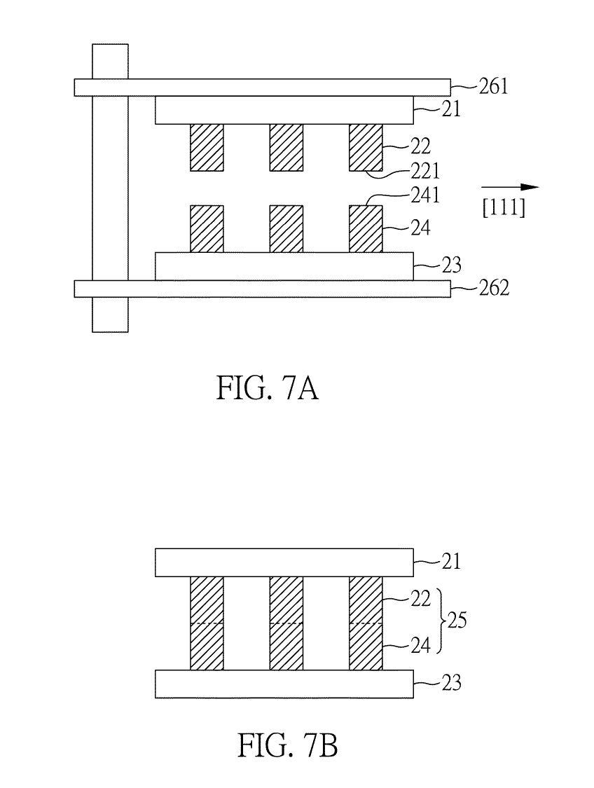

FIGS. 7A and 7B are cross-sectional views of a process for manufacturing the electrical connecting element having a nanotwinned copper of the present embodiment.

A plurality of the first copper films 22 and a plurality of the second copper films 24 are respectively formed on the first substrate 21 and the second substrate 23 in the present embodiment, as shown in FIGS. 7A and 7B. Herein, a plurality of the first copper films 22 and a plurality of the second copper films 24 can be respectively formed on the first substrate 21 and the second substrates 23 through the plating process described in Example 1 along with a lithography process. Herein, the first copper film 22 and the second copper film 24 respectively comprise a plurality of nanotwinned copper grains, the nanotwinned copper grains are composed by a plurality of nanotwinned copper, the nanotwinned copper grains are extended to the surface; and the [111] crystal axis is the axis vertical to the (111) surface. Thus, both the first connecting surface 221 of the first copper film 22 and the second connecting surface 241 of the second copper film 24 are (111) surfaces, and the ratios of (111) surfaces are 100%. The electron backscattered diffraction result thereof is the same as that shown in FIG. 4 of Example 1.

The first substrate 21 and the second substrate 23 are both semiconductor wafers in the present embodiment. Similarly, for the purpose of simply illustration, the structure of the first substrate 21 and the second substrate 23 are only represented by the schematic views, and the circuits or other components are not disclosed in the figures.

As shown in FIG. 7A, the first connecting surface 221 of the first copper film 22 and the second connecting surface 241 of the second copper film 24 are cleaned by an aqueous solution of hydrochloric acid (the volume ratio of a hydrochloric acid and the deionized water is 1:1) by the same method disclosed in Example 1. The first substrate 21 and the second substrate 23 are respectively placed on the clamps 261, 262, and the first connecting surface 221 is faced to the second connecting surface 241. Then, the first substrate 21 and the second substrate 23 are disposed in a vacuum furnace under 10⁻³ torr, the temperature of the vacuum furnace is raised to 200° C. to perform the connecting and annealing processes for 10 minutes to 1 hour. The twinned crystal structure of the first copper film 22, the second copper film 24 and the connecting portion therebetween can be maintained by moderately adjusting the added pressure during the connecting process.

After the aforementioned process, the electrical connection element having a twinned copper of the present embodiment can be obtained, as shown in FIG. 7B, which comprises: a first substrate 21; a second substrate 23; and a plurality of interconnects 25 which are located between the first substrate 21 and the second substrate 23, wherein the material of the interconnect 25 is nanotwinned copper, and 50% or more volume of the nanotwinned copper comprises a plurality of grains. Herein, the first copper films 22 and the second copper films 24 are connected to form the interconnects 25, and the connecting portion thereof are described as dotted lines.

### Example 3

The method for manufacturing a copper layer having (111) surface is shown as follows. First, a titanium layer (as an adhesion layer) with a thickness of 100 nm is deposited on the silicon wafer by a sputtering method, and then a copper layer having a (111) surface and a thickness of 200 nm is deposited on the titanium layer by a plating method. Herein, the copper layer can be prepared through the same plating process mentioned above. In the present embodiment, a silicon wafer with a copper layer having a (111) surface formed thereon is provided by the Amkor Technology Taiwan, INC. The ratio of the (111) surface can be controlled by forming different adhesion layer on the silicon wafer. Herein, 97% of the (111) surface can be obtained by using the titanium layer as an adhesion layer.

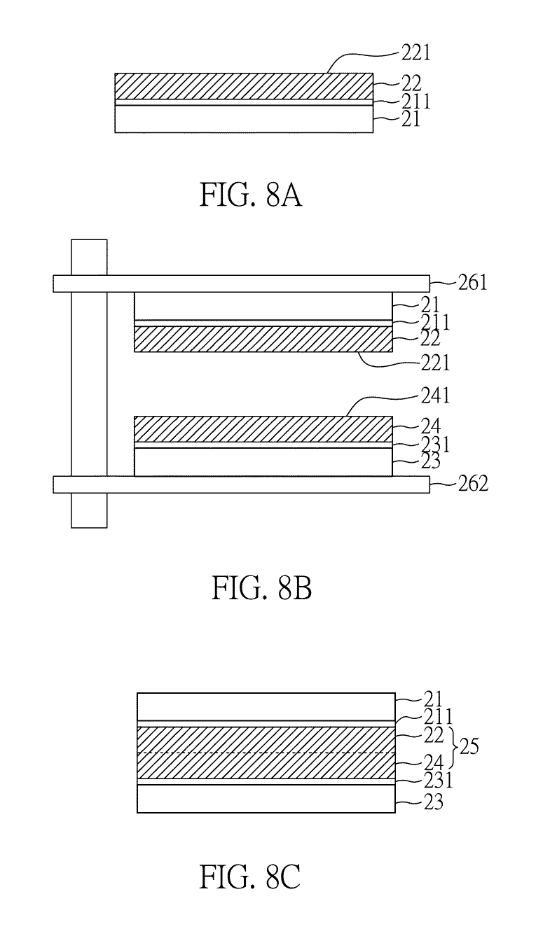

FIGS. 8A to 8C are cross-sectional views of a process for a manufacturing an electrical connecting element of the present embodiment; wherein the difference between the present embodiment and Example 1 is that the copper layer containing 97% of (111) surface as the connecting surface is used to replace the nanotwinned copper layer of Example 1.

First, as shown in FIG. 8A, a first substrate 21, which is a silicon substrate, is provided; and a first adhesion layer 221 is formed thereon which is a titanium layer with a thickness of 100 nm. However, the first adhesion layer of the present embodiment is only used for connecting the silicon substrate with the following formed copper layer well, and the material of the first adhesion layer can be changed or the first adhesion layer is not used based on the material of the substrate. In addition, in order to illustrate briefly, only the schematic diagram the first substrate 21 is exemplified, and circuits, active components, passive components or other components are not disclosed in the drawings.

Then, a first copper layer 22 is formed on the first adhesion layer 221 of the first substrate 21, the first copper layer 22 is a copper layer having a (111) surface, and a thickness thereof is around 200 nm.

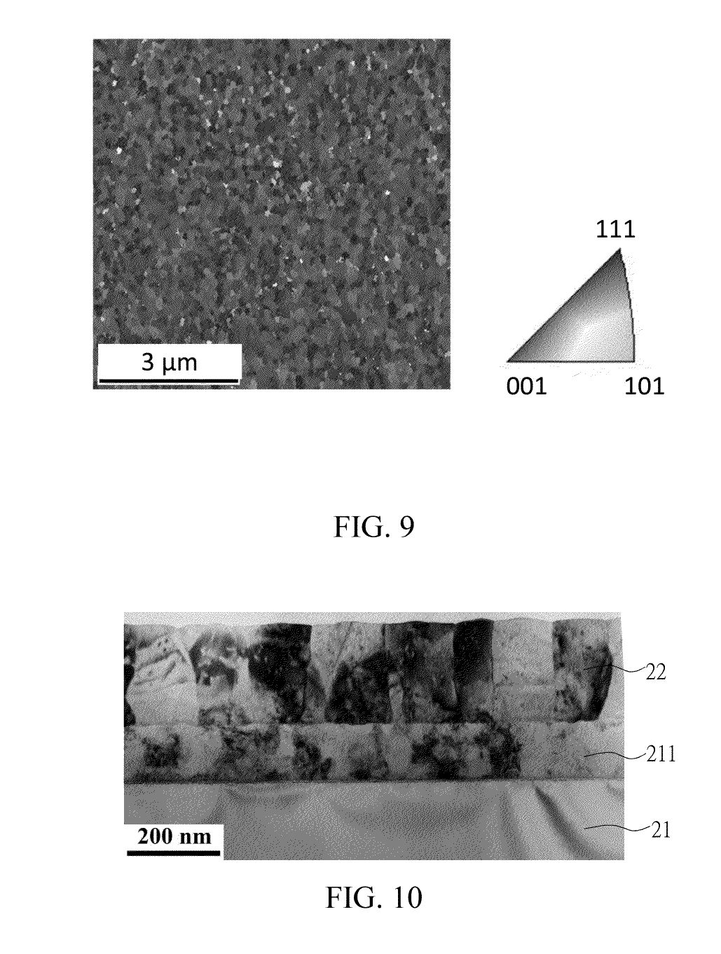

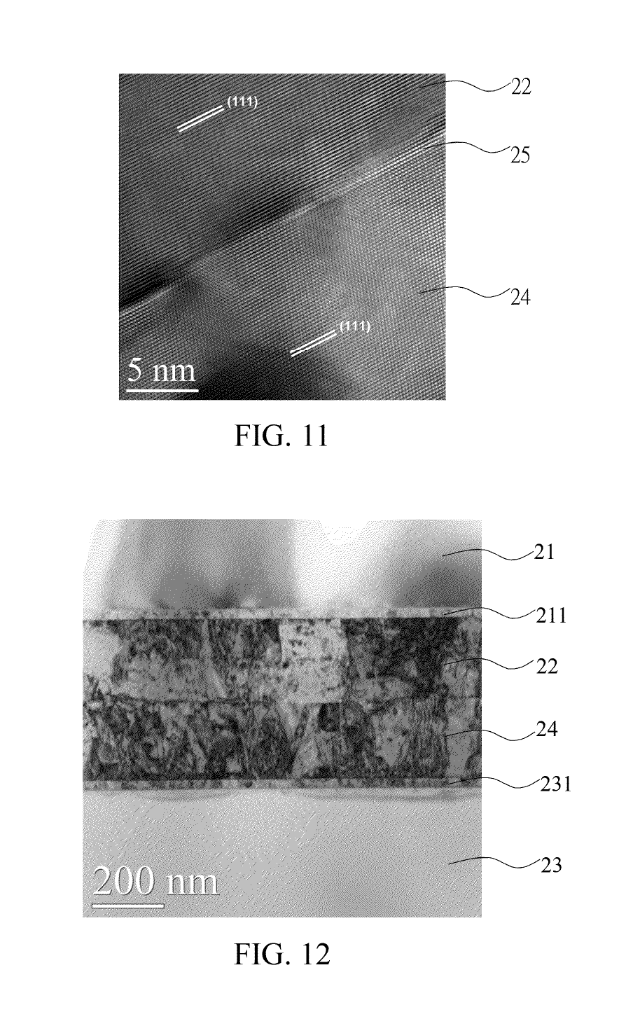

After an electron backscattered diffraction (EBSD) analysis, as shown in FIG. 9, 97% or more of the copper layer surface are prepared in the present embodiment is a (111) surface, wherein the area of the blue part is (111) surface. Further, the cross section of the copper layer is analyzed with a transmission electron microscope (TEM), and the result indicates that the copper layer prepared by the present embodiment is present in a columnar structure (columnar crystal grains), as shown in FIG. 10. Furthermore, it was found that the long axis of the copper layer is in [111] direction, which is observed by a X-ray diffraction image analysis; and the cross section of the copper layer analyzed by the high resolution transmission electron microscope (HRTEM) also shows that the surface of the copper layer prepared in the present embodiment is a (111) surface, as shown in the FIG. 11.

As shown in FIG. 8B, a second substrate 23 which is a silicon substrate is provided, and a second adhesion layer 231 is formed thereon. Then, a second copper layer 24 is formed on the second adhesion layer 231 of the second substrate 23, which is a copper layer having a (111) surface with a thickness about 200 nm. The process, material, thickness and function of the second adhesion layer 231 and the second copper layer 24 are respectively similar to the above mentioned first adhesion layer 211 and the first copper layer 22, so those are not further described herein. Besides, for the purpose of brief description, only the schematic view of the second substrate 23 is exemplified, and the circuits, active components, passive components or other components are not illustrated in the drawings.

Then, as shown in FIG. 8B, the first connecting surface 221 of the first copper film 22 and the second connecting surface 241 of the second copper film 24 are respectively cleaned with an aqueous solution of hydrochloric acid (wherein, the volume ratio of a hydrochloric acid and the deionized water is 1:1). The first substrate 21 and the second substrate 23 are respectively placed on the clamps 261, 262, and the first connecting surface 221 is faced to the second connecting surface 241. Then, the first substrate 21 and the second substrate 23 are placed in a vacuum furnace under 10⁻³ torr, the temperature of the vacuum furnace is raised to 200° C. to perform the connecting and annealing processes for 1 hour, and pressure (about 3 Kg/cm²) is moderately applied to the first substrate 21 and the second substrate 23 during the period of connecting.

The electrical connection element containing (111) without twinned copper of the present embodiment can be obtained via the above mentioned process, as shown in FIG. 8C, which comprises: a first substrate 21; a second substrate 23; and an interconnect 25 which is located between the first substrate 21 and the second substrate 23, wherein the interconnect 25 is made of the first copper layer 22 connecting to the second copper layer 24, the junction between the first copper layer 22 and the second copper layer 24 comprises a plurality of grains, and the grains are formed by stacking along a stacking direction of [111] crystal axis. Herein, the first copper layer 22 and the second copper layer 24 form the interconnect 25 by connecting and the connecting portion (i.e. the connecting surface) is represented by a dotted line.

FIG. 12 is a TEM photo showing the cross section of the electrical connecting element formed by a copper layer of the present embodiment. Although the copper layer without nanotwinned structure is used in the present embodiment, there are no holes or gaps formed in the connecting portion (i.e. the connecting surface) and a columnar grain structure can be maintained due to the (111) surface of the copper layer. Meanwhile, the HRTEM image of the cross section of the copper layer also shows that the connection interface is a grain boundary and no oxidant layer is observed, as shown in the FIG. 11.

### Example 4

As shown in FIG. 8A to FIG. 8C, the material, manufacturing process and the structure of this embodiment are the same as those described in the Example 3, except that the first copper layer 22 on the first substrate 21 of the present embodiment is a polycrystalline layer having a (111) surface (the first connecting surface 221) and has a thickness of about 2 μm; and the second copper layer 24 of the second substrate 23 is a copper layer without a (111) surface (the second connecting surface 241) and has a thickness of about 2 μm. In addition, the connecting process is performed under 10⁻³ torr, the connecting temperature is 200° C., the applied pressure is about 4 kg/cm², and the connecting time is 1 hour.

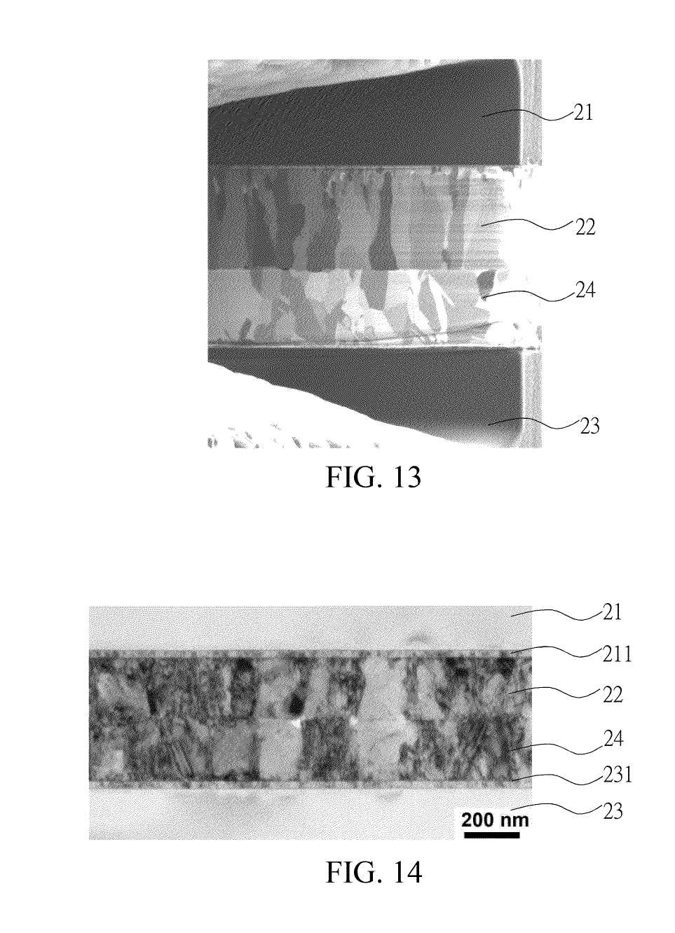

FIG. 13 is a focused ion beam (FIB) cross-sectional view of a connecting portion of the electrical connecting element of the present embodiment. The result shows that, there are no holes or gaps formed in the connecting portion (i.e. the connecting surface) even though the copper layer without nanotwinned structure is used and only one connecting surface 221 being a (111) surface is used in the present embodiment.

The above results show that when using a copper layer having high preferred direction [111], only one connecting surface but not both the connecting surface has to be a (111) surface, the purpose of connecting the copper layers under a condition of low vacuum, low pressure and low temperature can be achieved, and there is no oxidant layer formed in the connecting portion. Meanwhile, due to the low connecting temperature, the connected copper layer (i.e. the connecting portion) still has a columnar crystal structure having [111] preferred direction.

### Example 5

As shown in FIG. 8A to FIG. 8C, the material, manufacturing process and the structure of this embodiment are the same as those described in the Example 3, except that the first copper layer 22 on the first substrate 21 and the second copper layer 24 of the second substrate 23 of the present embodiment are both nanotwinned copper layers, and both the first connecting surface 221 and the second connecting surface 241 have 97% of (111) connecting surface based on the total area of the first connecting surface 221 and the second connecting surface 241. Besides, the connecting process is performed under 10⁻³ torr, the connecting temperature is 250° C., the applied pressure is about 100 psi, and the connecting time is 10 minutes.

The electron backscattered diffraction diagram of the copper layer of the present embodiment is the same as that shown in FIG. 9 of Example 3. According to the image shown in FIG. 9, the result shows that both the first connecting surface 221 and the second connecting surface 241 contain 97% of the (111) connecting surface, and the blue part shown therein is a (111) surface. In addition, according to the bright field image observed by the transmission electron microscope shown in FIG. 14, there are no holes or gaps formed in the connecting portion (i.e. the connecting surface).

### Example 6

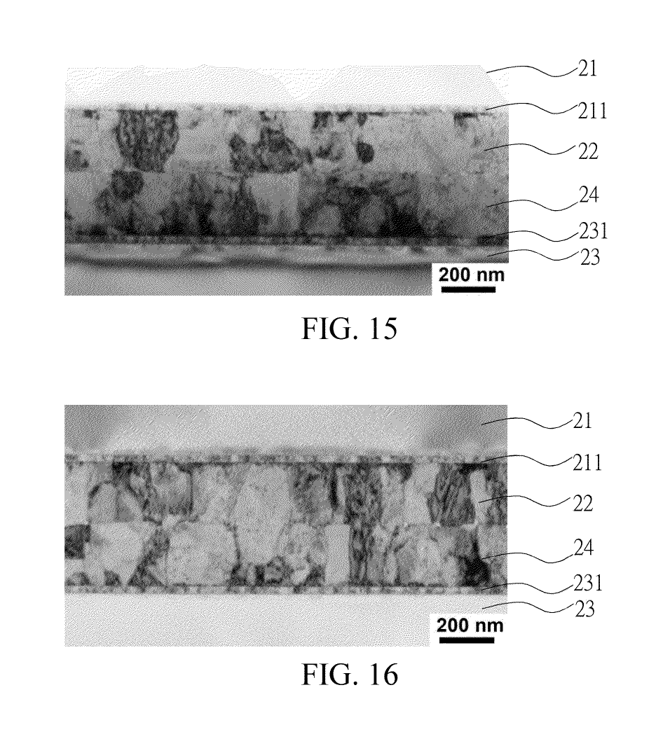

The material, manufacturing process and the structure of this embodiment are the same as those described in Example 5, except that the connecting process is performed under 10⁻³ torr, the connecting temperature is 200° C., the applied pressure is about 100 psi, and the connecting time is 30 minutes. According to the bright field image observed by the transmission electron microscope shown in FIG. 15, there are no holes or gaps formed in the connecting portion (i.e. the connecting surface).

### Example 7

The material, manufacturing process and the structure of this embodiment are the same as those illustrated in Example 5, except that the connecting process is performed under 10⁻³ torr, the connecting temperature is 150° C., the applied pressure is about 100 psi, and the connecting time is 60 minutes. According to the bright field image observed by the transmission electron microscope shown in FIG. 16, there are no holes or gaps formed in the connecting portion (i.e. the connecting surface).

### Example 8

As shown in FIG. 8A to FIG. 8C, the material, manufacturing process and the structure of this embodiment are the same as those illustrated in Example 3, except that the first copper layer 22 on the first substrate 21 and the second copper layer 24 of the second substrate 23 of the present embodiment are both nanotwinned copper layers, and both the first connecting surface 221 and the second connecting surface 241 have 64% of (111) connecting surface based on the total area of the first connecting surface 221 and the second connecting surface 241. Besides, the connecting process is performed under 10⁻³ torr, the connecting temperature is 200° C., the applied pressure is about 100 psi, and the connecting time is 30 minutes.

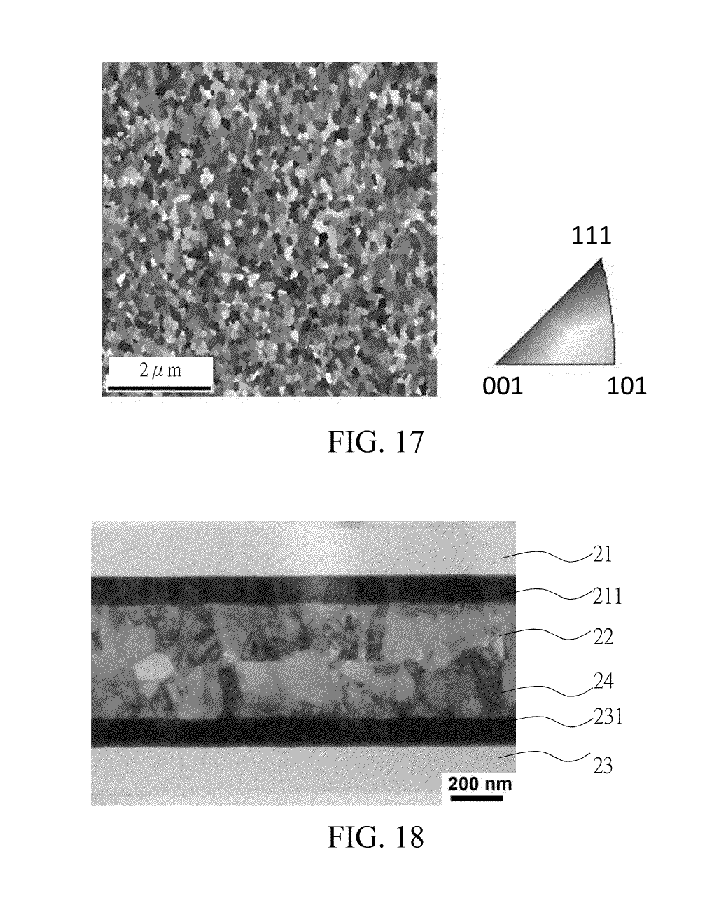

FIG. 17 is an electron backscattered diffraction of the copper layer of the present embodiment. As shown in FIG. 17, both the first connecting surface 221 and the second connecting surface 241 used in the present embodiment contain 64% of the (111) connecting surface, and the blue part shown therein is a (111) surface. The ratio of the (111) surface can be controlled by using different connecting layers on the silicon wafer. In the present embodiment, a titanium tungsten layer is used as an adhesion layer to obtain a copper layer having 64% of the (111) surface formed thereon. Besides, according to the bright field image observed by the transmission electron microscope shown in FIG. 18, there are no holes and gaps formed in the connecting portion (i.e. the connecting surface).

The above mentioned results show that when using a copper layer having high preferred direction [111], even though only 50% of the connecting surface is a (111) surface, the purpose of connecting the copper layers under a condition of low vacuum, low pressure and low temperature can be achieved, and there are no holes or gaps formed in the connecting interface. Meanwhile, due to the low connecting temperature, the connected copper layer (i.e. the copper film) still has the columnar crystal structure having [111] preferred direction.

### Example 9

As shown in FIG. 8A to FIG. 8C, the material, manufacturing process and the structure of this embodiment are the same as those illustrated Example 1, except that the second copper layer 24 of the second substrate 23 is substituted with a gold film, and the second substrate 23 is a silicon substrate with a silicon dioxide layer and a titanium layer sequentially laminated thereon. Herein, the gold film is formed with a FCTD-0056-6 Microfab Au100 plating solution (which is purchased from the Electroplating Engineers of Japan Ltd. Later), and the DC plating process is performed with a current density of 5 ASD at room temperature to form a gold film having a thickness of 100 nm, which has (220) preferred direction. Moreover, the connecting process is performed under 10⁻³ torr, the connecting temperature is 200° C., the applied pressure is about 4 kg/cm², and the connecting time is 1 hour.

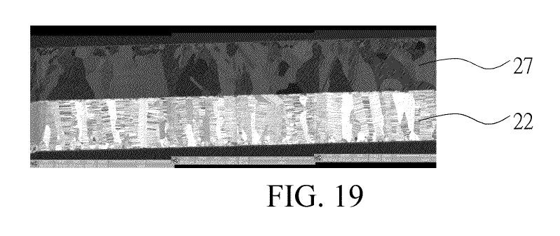

FIG. 19 is a focused ion beam (FIB) cross-sectional view of a connecting portion of the electrical connecting element of the present embodiment. As shown in FIG. 19, there are no holes or gaps formed in the connecting interface between the first copper layer 22 having (111) connecting surface (i.e. the nanotwinned copper film) and the gold film 27, and this result indicates that a good interconnect formed with the nanotwinned copper film and the gold film can be obtained by direct connecting the same.

According to the foregoing results, when using a copper layer having high preferred [111] direction, even though the first metal film is the gold film which is made of a hetero material other than copper, the purpose of connecting the metal film and the copper film under a condition of low vacuum, low pressure and low temperature can still be achieved, and there are no holes or gaps formed in connecting interface. Meanwhile, due to the low connecting temperature, the connected copper layer (i.e. the copper film) still has a columnar crystal structure having [111] preferred direction.

Although the present invention has been explained in relation to its preferred embodiment, it is to be understood that many other possible modifications and variations can be made without departing from the spirit and scope of the invention as hereinafter claimed.

What is claimed is:

1. A method for manufacturing an electrical connecting element for electrical connecting a first substrate and a second substrate, comprising the following steps:
(A) providing a first substrate and a second substrate, wherein a first copper film is formed on the first substrate, a first metal film is formed on the second substrate, a first connecting surface of the first copper film is a (111)-containing surface, and the first metal film has a second connecting surface; and
(B) connecting the first copper film and the first metal film to form an interconnect, wherein the first connecting surface of the first copper film is faced to the second connecting surface of the first metal film.

2. The method of claim 1, wherein both the first connecting surface of the first copper film and the second connecting surface of the first metal film are (111)-containing surfaces.

3. The method of claim 1, wherein the first copper film comprises a plurality of copper grains having (111) surfaces, and 40-100% of a total area of the (111)-containing surface is (111) surface on a basis that an angle of 15° included between a normal vector of the (111) surface of the copper grain and a normal vector of the (111)-containing surface is defined as the (111) surface.

4. The method of claim 1, wherein a material of the first metal film is selected from a group consisting of gold, silver, platinum, nickel, copper, titanium, aluminum and palladium.

5. The method of claim 1, wherein the first metal film is a second copper film.

6. The method of claim 5, wherein the first copper film and the second copper film respectively are a copper layer having a connecting surface containing (111) surface or a nanotwinned copper layer.

7. The method of claim 1, further comprising a step (A′) prior to the step (A): cleaning the first connecting surface of the first copper film and the second connecting surface of the first metal film with an acid.

8. The method of claim 6, wherein 50% or more volume of the nanotwinned copper layer comprises a plurality of grains.

9. The method of claim 7, wherein the grains are columnar twinned grains.

10. The method of claim 8, wherein the grains are interconnecting with each other, each grain is formed by a plurality of nanotwinned copper stacking along a stacking direction of [111] crystal axis, and an angle included between the stacking directions of adjacent grains is 0-20°.

11. The method of claim 1, wherein the first copper film and the first metal film are connected with each other with a pressure in the step (B).

12. The method of claim 1, wherein the first copper film and the first metal film are connected with each other with a pressure under 100-400° C. in the step (B).

13. The method of claim 1, wherein the first copper film and the first metal film are connected with each other under 1-10⁻³ torr in the step (B).

14. An electrical connecting element for electrical connecting a first substrate and a second substrate, comprising:
a first substrate;
a second substrate; and
an interconnect disposed between the first substrate and the second substrate, wherein the interconnect is formed by connecting a first copper film and a first metal film to each other, and a junction between the first copper film and the first metal film comprises a plurality of grains, which stacks along a stacking direction of [111] crystal axis.

15. The electrical connecting element of claim 14, wherein the grains are columnar grains.

16. The electrical connecting element of claim 14, wherein a material of the first metal film is selected from a group consisting of gold, silver, platinum, nickel, copper, titanium, aluminum, and palladium.

17. The electrical connecting element of claim 14, wherein the first copper film is a copper layer having a connecting surface containing (111) surface, or a nanotwinned copper layer.

18. The electrical connecting element of claim 17, wherein 50% or more volume of the nanotwinned copper layer comprises a plurality of grains.

19. The electrical connecting element of claim 18, wherein the grains are columnar twinned grains.

20. The electrical connecting element of claim 18, wherein the grains interconnects with each other, each grain is formed by a plurality of nanotwinned copper stacking along the stacking direction of [111] crystal axis, and an angle included between the stacking directions of adjacent grains is 0-20°.
